(19) United States
(12) Patent Application Publication
(10) Pub. No.: US 2013/0341073 A1
(43) Pub. Date: Dec. 26, 2013

(54) PACKAGING SUBSTRATE AND METHOD FOR MANUFACTURING SAME

(71) Applicant: ZHEN DING TECHNOLOGY CO., LTD., Tayuan (TW)

(72) Inventors: CHE-WEI HSU, Taoyuan (TW); SHIH-PING HSU, Taoyuan (TW)

(73) Assignee: ZHEN DING TECHNOLOGY CO., LTD., Tayuan (TW)

(21) Appl. No.: 13/864,278

(22) Filed: Apr. 17, 2013

(30) Foreign Application Priority Data
Jun. 20, 2012 (CN) 201210204790.6

(51) Int. Cl. H05K 3/40; H05K 3/00; H05K 1/11

(52) U.S. Cl. CPC H05K 3/4038; H05K 1/113; H05K 3/0094
USPC 174/254; 29/852

(57) ABSTRACT

A packaging substrate includes an insulating layer, a wiring layer and a solder mask. The insulating layer and the solder mask being arranged on two opposite sides of the wiring layer. The insulating layer defines a via hole. The wiring layer covers the via hole. The wiring layer includes a pad area. Two sides of the pad area are respectively exposed outside from the solder mask and in the via hole.

### BACKGROUND

1. Technical Field

The present disclosure relates to a packaging substrate for mounting a chip and a method for manufacturing the packaging substrate.

2. Description of Related Art

Chip packages may include a packaging substrate and a chip. The printed circuit board (PCB) is configured to form a connecting pad. Most of the packaging substrates include a plurality of patterned electrically conductive layers, which make the packaging substrate thick.

What is needed therefore is a packaging substrate, a method for manufacturing the same and a chip package having the packaging substrate to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of a roll of flexible copper clad laminate according to an exemplary embodiment, the flexible copper clad laminate including a copper layer and an insulating layer.

FIG. 2 is a schematic, cross-sectional view of part of the flexible copper clad laminate of FIG. 1.

FIG. 3 shows a plurality of via holes to penetrate the insulating layer of FIG. 2.

FIG. 4 shows a second dry film photoresist layer and a third dry film photoresist layer formed on the single-sided strip-shaped flexible copper clad laminate in FIG. 3.

FIG. 5 shows a wiring layer obtained by patterning the copper layer of FIG. 4.

FIG. 6 is a schematic view of a sheet obtained by cutting the patterned flexible copper clad laminate, the sheet having a plurality of substrate strips.

FIG. 7 shows a solder mask formed on the sheet of FIG. 6 to cover the entire surface except pad or finger areas defined at predetermined positions on the wiring layer.

FIG. 8 shows a thin copper layer formed on the insulation layer of the sheet in FIG. 7.

FIG. 9 shows a first dry film photoresist layer formed on the thin copper layer of FIG. 7.

FIG. 10 shows a plating layer formed on the pad or finger areas in FIG. 8, the third dry film photoresist layer removed from the thin copper layer, and the thin copper layer removed from the insulating layer.

FIG. 11 is a schematic view of a substrate strip with circuit board units obtained by stripping the sheet with plating layer of FIG. 10.

FIG. 12 is a schematic view of a packaging substrate obtained by cutting the substrate trip of FIG. 11, the packaging substrate being the circuit board unit.

FIG. 13 shows an electrically conductive material formed in each via hole of the packaging substrate in FIG. 12 to obtain a packaging substrate with electrically conductive material.

FIG. 14 shows a supporting board on the package substrate of FIG. 13.

### DETAILED DESCRIPTION

A packaging substrate and a method for manufacturing the packaging substrate according to embodiments will be described with reference to the drawings.

A method of manufacturing a packaging substrate according to an exemplary embodiment includes the steps as follows.

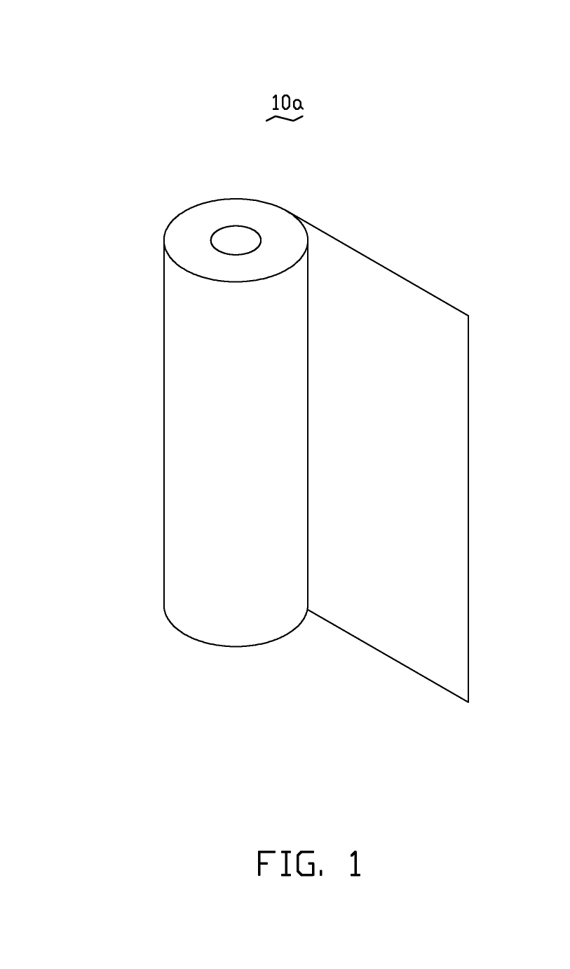

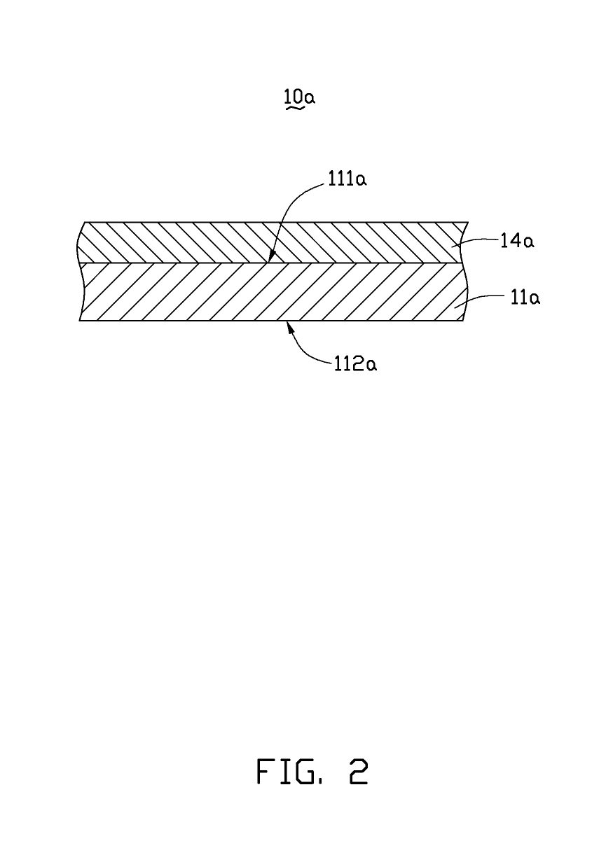

FIGS. 1 and 2 show step 1, a roll of flexible copper clad laminate 10a is provided. The flexible copper clad laminate 10a includes an insulating layer 11a and a copper layer 14a. The insulating layer 11 a includes a first surface 111a and a second surface 112a facing away from the first surface 111a. The copper layer 14a covers the first surface 111a. The insulating layer 11a may be made of flexible material, for example, Polyimide, Polyethylene Naphthalate, Polyethylene Terephthalate. In the present embodiment, the insulating layer 11a is Polyimide. The thickness of the insulating layer 11a is in a range from 15 micrometers to 250 micrometers, and preferably from 25 micrometers to 50 micrometers. The copper layer 14a may be a roll copper foil, an electrolytic foil, for example. The thickness of the copper layer 14a is in a range from about 12 micrometers to about 35 micrometers.

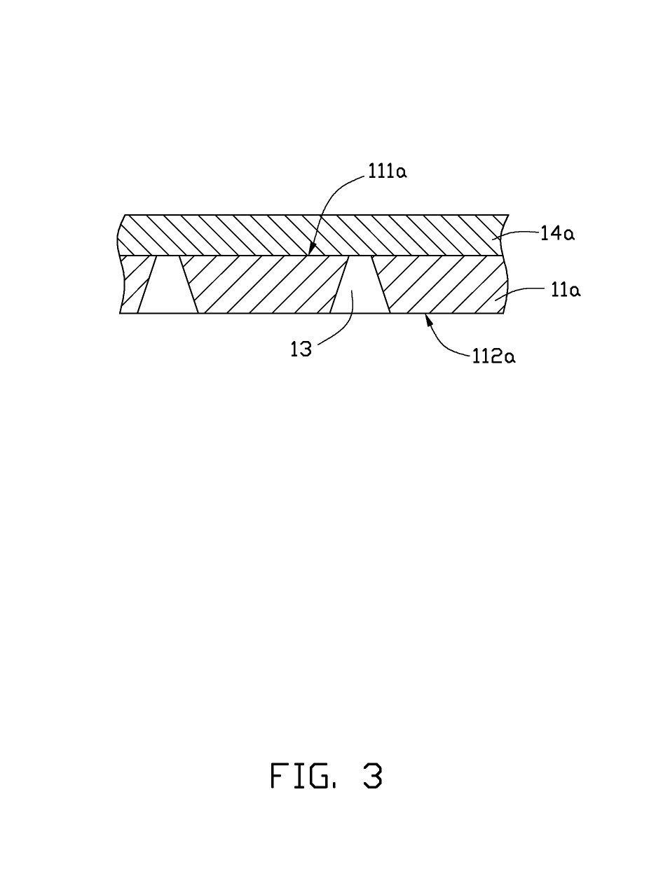

FIG. 3 shows step 2, in which a plurality of via holes 13 are defined in the copper clad laminate 10a. Each via hole 13 penetrates the insulating layer 11a. That is, each via hole 13 passes through the first surface 111a and the second surface 111b. The via holes 13 may be formed by a laser beam or a blanking die. In the present embodiment, the via holes 13 are formed by a laser beam, and a cross section of each via hole 13 taken in a plane parallel with the first surface 111a is round. In other embodiments, the cross section of each via hole 13 taken in a plane parallel with the first surface 111a may be square, or triangle, for example.

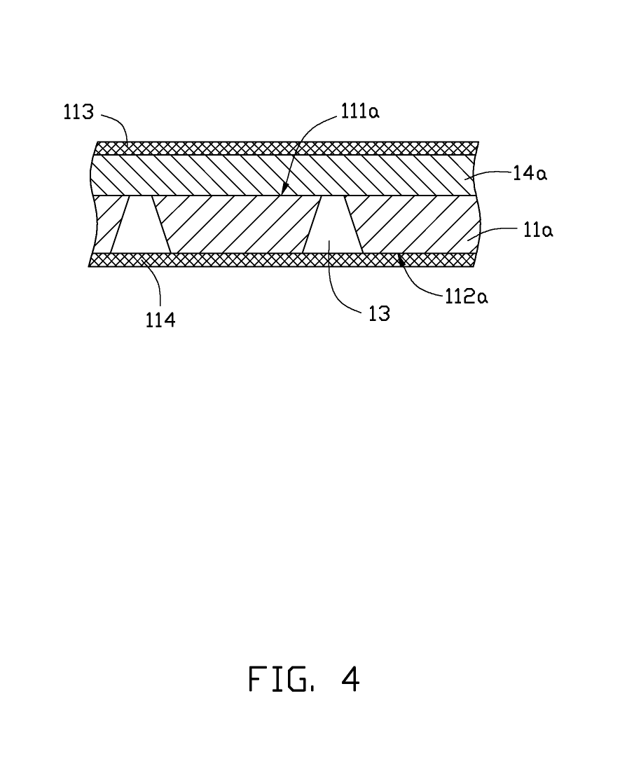

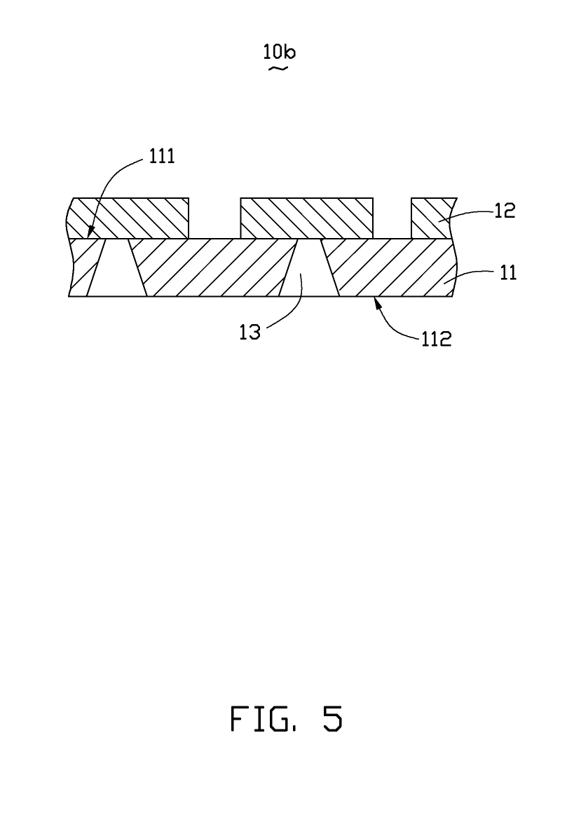

FIGS. 4 and 5 shows steps 3, in which the copper layer 14a is patterned to form a wiring layer 12. In the present embodiment, the copper layer 14a is converted into the wiring layer 12 by an image transfer process and an etching process. The method for manufacturing the wiring layer 12 includes the following steps.

First, the surfaces of the copper layer 14a and the insulating layer 11 a are processed by a surface etching process to remove contaminants, from the surfaces of the copper layer 14a and the insulating layer 11a. In addition, lightly etch the surface of the copper layer 14a to make the surface of the copper layer 14a rough, thereby improving a cohesion force between the copper layer 14a and a dry film photoresist layer (described below). Thus, bubbles and contaminants are prevented from being generated between the copper layer 14a and the dry film photoresist layer. In other embodiments, the surfaces of the copper layer 14a and the insulating layer 11 a may be processed by plasma treatment.

Second, as FIG. 4 shows, a second dry film photoresist layer 113 is laminated onto the copper layer 14a, and a third dry film photoresist layer 114 is laminated onto the second surface 112. In other embodiments, the second surface 112 may be covered with a coverlay, an adhesive tape, for example.

Third, as FIG. 5 shows, the copper layer 14a is patterned to form the wiring layer 12 by a exposing process, a developing process, a etching process, and a striping process, thereby obtaining a roll of patterned flexible copper clad laminated 10b. In the present embodiment, the second dry film photoresist layer 113 is selectively exposed. The exposed second dry film photoresist layer 113 is developed to be converted into a patterned dry film photoresist layer, such that portions of the copper layer 14a, which will be removed, are exposed from the patterned dry film photoresist layer, and the other portions of the copper layer 14a, which will be converted into the a wiring layer 12, are covered by the patterned dry film photoresist layer. The portions of the copper layer 14a, which will be removed, are etched by copper-etching solution to be removed from insulating layer 11a, thereby converting the other portions of the copper layer 14a, which is covered by the patterned dry film photoresist layer, into the a wiring layer 12. The wiring layer 12 cover the via holes 13. Striping means stripping the patterned dry film photoresist layer and the third dry film photoresist layer 114 off the wiring layer 12 and the second surface 112a, such that the a wiring layer 12 and the second surface 112 are exposed. In other embodiments, the copper layer 14a is converted into the wiring layer 12 by a wet film processing. In addition, after converting the copper layer 14a into the wiring layer 12, there may be a step of forming a plurality of tooling holes (not shown) by a punching process. The tooling holes pass through the insulating layer 11a and the wiring layer 12, and are configured for locating the circuit board in the following steps.

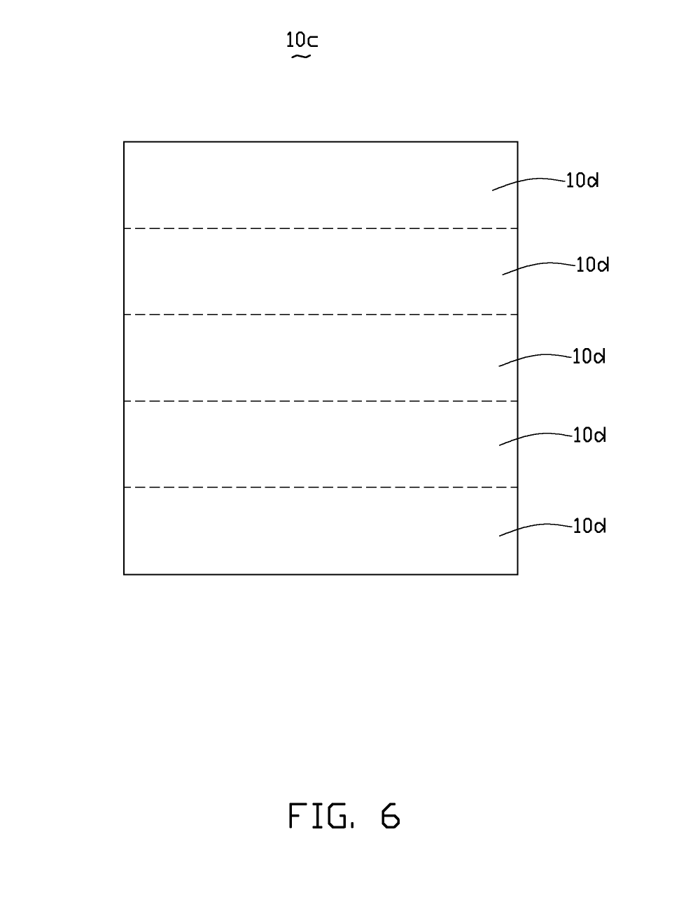

FIGS. 5 and 6 shows steps 4, in which the patterned flexible copper clad laminated 10b is cut from roll type into a plurality of sheets 10c. Each sheet 10c includes a plurality of substrate strip 10d without a solder mask. Each substrate strip 10d includes a plurality of via holes 13. Wherein before the step of cutting the patterned flexible copper clad laminate 10b, the flexible copper clad laminate 10a is transferred to each adjoined process in a roll-to-roll manner.

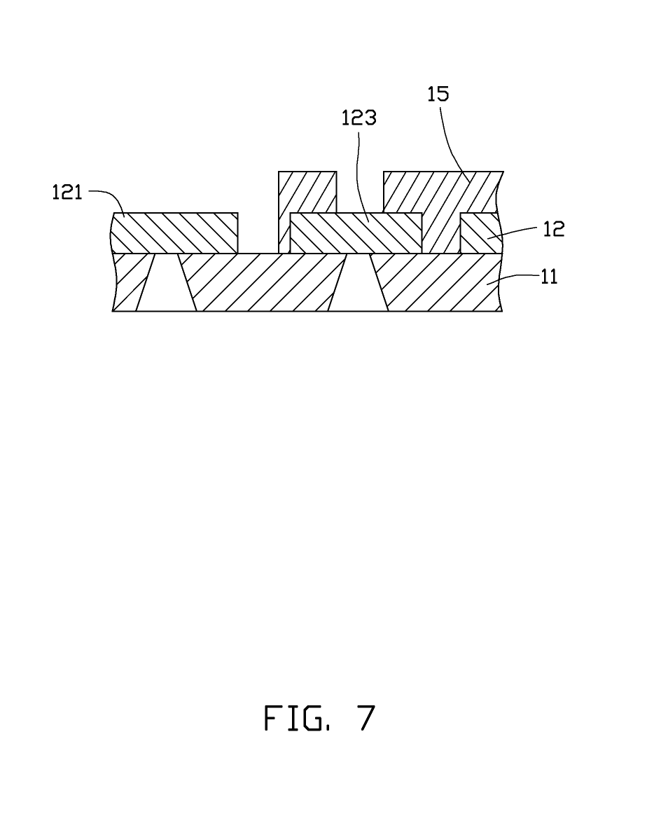

FIGS. 7 shows steps 5, in which a solder mask 15 is formed on the wiring layer 12 of the sheet 10c to cover the entire surface of the wiring layer 12 except pad areas 123 or finger areas 121 defined at predetermined positions on the wiring layer 12. In the present embodiments, each of pad areas 123 or fingers areas 123 spatially corresponds to a via hole 13; the finger areas 121 are located at an edge of the wiring layer 12, and the pad areas 123 are located at a central area of the wiring layer 12.

In the present embodiment, the solder mask 15 is made of liquid photoimageable solder resist ink. The method for forming the solder mask 15 includes the following steps: first, printing the liquid photoimageable solder resist ink on the entire surface of the wiring layer 12, selectively exposing the liquid photoimageable solder resist ink by a ultraviolet light to make first portions of the liquid photoimageable solder resist ink generate a cross-linking reaction, in which the first portions spatially correspond the pad areas 123 and finger areas 121; removing second portions of the liquid photoimageable solder resist ink which does not generate a cross-linking reaction, from the wiring layer 12 by a developing process; finally, thermal curing the retaining liquid photoimageable solder resist ink, thereby forming the solder mask 15. There may be one finger area 121, or any number of finger areas 121. There may be one pad area 123, or any number of pad areas 123. For better understand, there is one finger area 121 shown in figures and there is one pad area 123 shown in figures.

In other embodiments, the solder mask 15 may be made of a thermosetting ink. In such case, exposing and developing can be omitted, and the thermosetting ink is printed on the entire surface of the wiring layer 12 except pad areas 123 or finger areas 121 defined at predetermined positions on the wiring layer 12 using a patterned screen. Then, the thermosetting ink is cured to obtain the solder mask 15.

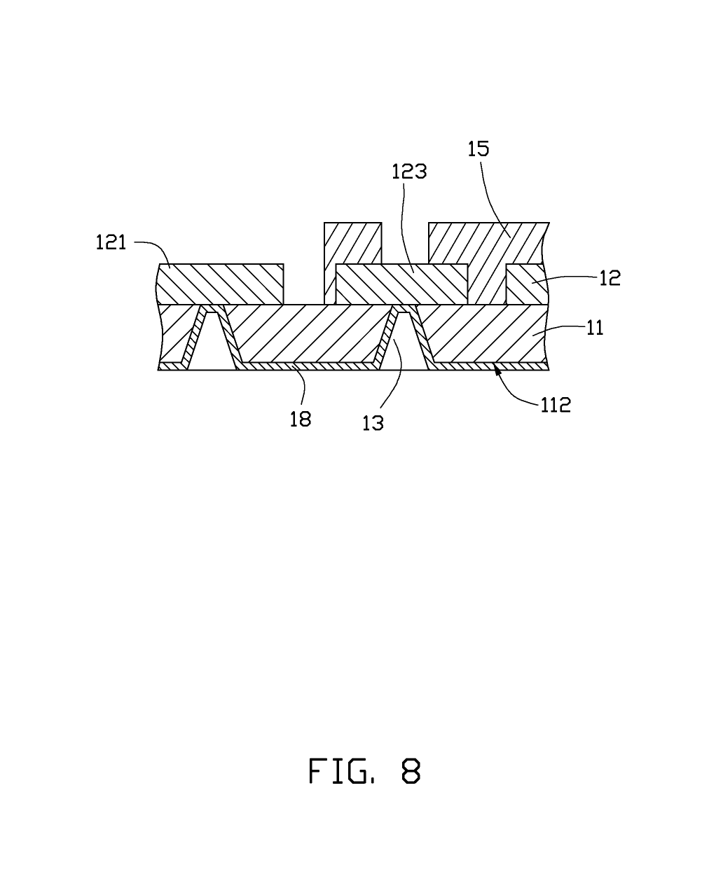

FIGS. 8 to 10 show step 6, in which a plating layer 122 is formed on the finger area 121 by plating, a plating layer 124 is formed on the pad area 123 by plating. Thus, a sheet 10e with the plating layers (i.e. a plated sheet) is obtained. The plating layer 122 includes gold. The plating layer 124 includes nickel and gold. The plating layer 122 and the plating layer 124 are configured for protecting the finger area 121 and the pad area 123 from being oxidized, and the plating layer 122 and the plating layer 124 may be formed by the following steps.

First, FIG. 8 shows that a thin copper layer 18 is formed on the second surface 112, the inner surface of the via holes 13, and the surface of finger area 121 exposed at the side of the second surface 112, and the surface of the pad area 122 exposed at the side of the second surface 112 by sputtering. In other embodiments, the thin copper layer 18 may be formed by an electro-less copper plating.

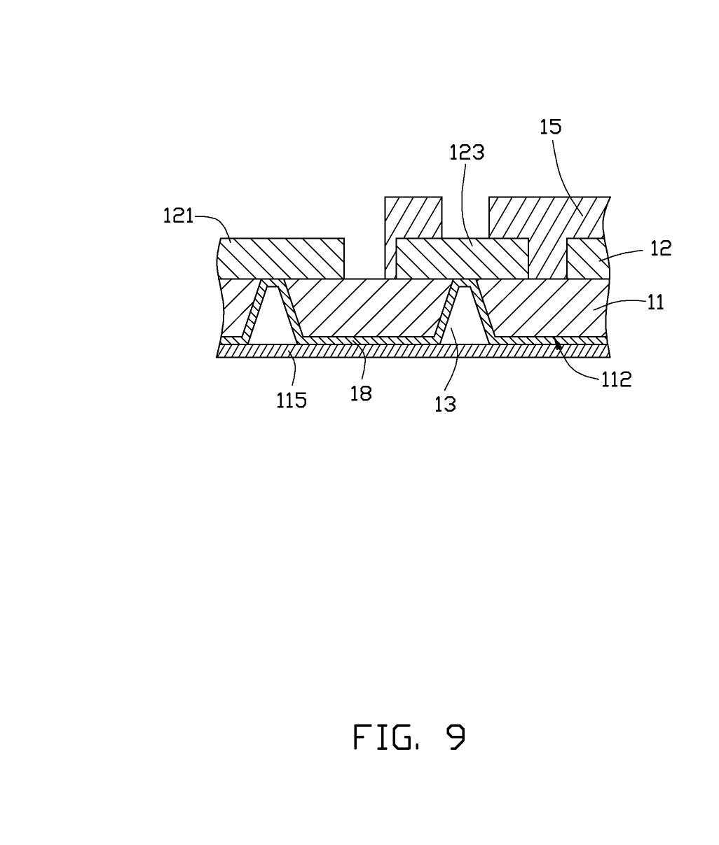

Second, FIG. 9 shows that a first dry film photoresist layer 115 is laminated on the thin copper layer 18, and the first dry film photoresist layer 115 is entirely exposed to make the first dry film photoresist generate cross-linking reaction. The first dry film photoresist layer 115 is configured for protecting the thin copper layer 18 from being etched and contaminated by gold plating solution, and for preventing the thin copper layer 18 from being plated with gold. The reason of wholly exposing the first dry film photoresist layer 115 is that the exposed first dry film photoresist layer 115 can substantially resist the gold plating solution. In alternative embodiments, if portions of the thin copper layer 18 need to be plated with gold, the first dry film photoresist layer 115 may be selectively exposed and developed. In further alternative embodiments, the thin copper layer 18 may be covered with an anti-plating film or an anti-plating adhesive tape to replace the first dry film photoresist layer 115. In still further alternative embodiments, the thin copper layer 18 may be printed with a peelable solder mask ink to replace the first dry film photoresist layer 115.

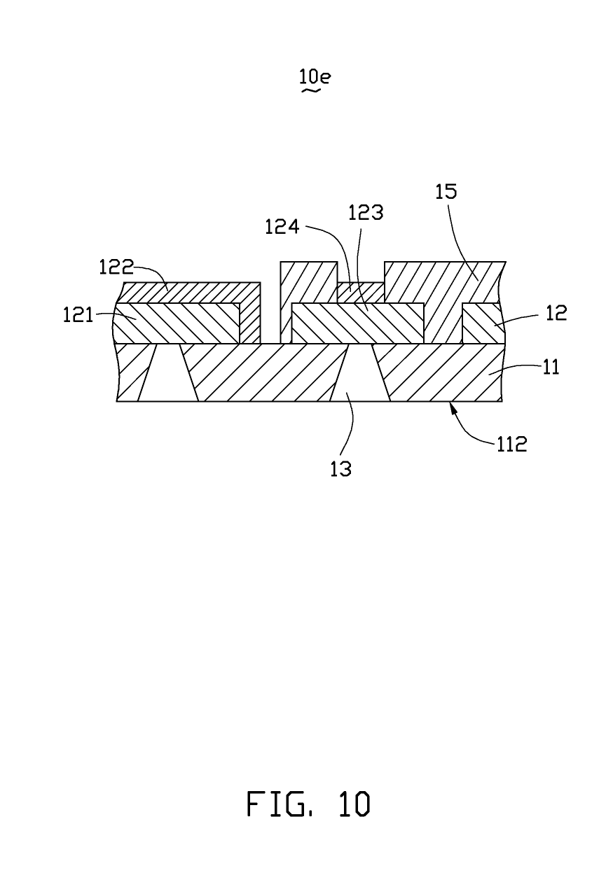

Finally, FIG. 10 shows that the plating layer 122 and the plating layer 124 are respectively formed on the finger area 121 and the pad area 123 by electroplating, and the exposed first dry film photoresist layer 115 and the thin copper layer 18 are removed from the insulating layer 11. In other embodiments, silver layer or tin layer may be formed on the finger area 121 and the pad area 123 to replace the plating layer 122 and the plating layer 124.

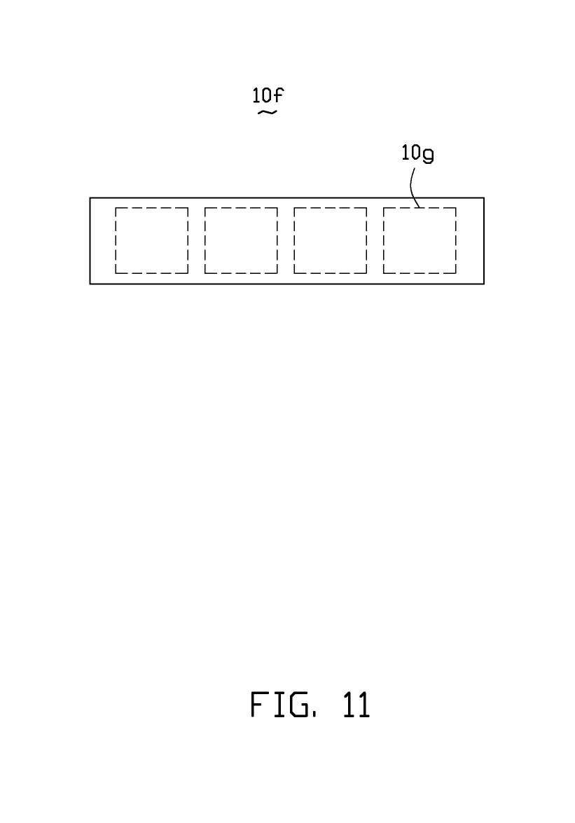

FIG. 11 shows steps 6, in which the sheet 10e with plating layer 122 and the plating layer 124 is stripped into a plurality of substrate strips 10f with plating layer 122 and the plating layer 124 and solder mask 15. Each substrate strip 10f includes a plurality of circuit board units 10g. Each circuit board unit 10g includes at least one via hole 13. In the present embodiment, each circuit board unit 10g includes at least two via hole 13.

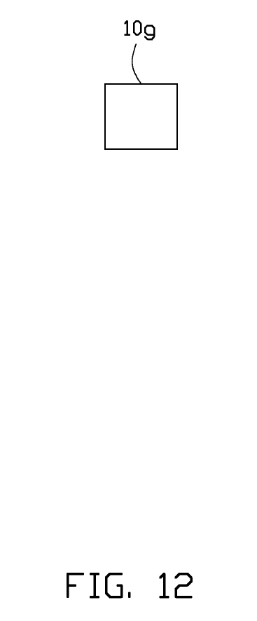

FIG. 12 shows steps 7, in which the substrate strip 10f is cut into a plurality of separate circuit board units 10g.

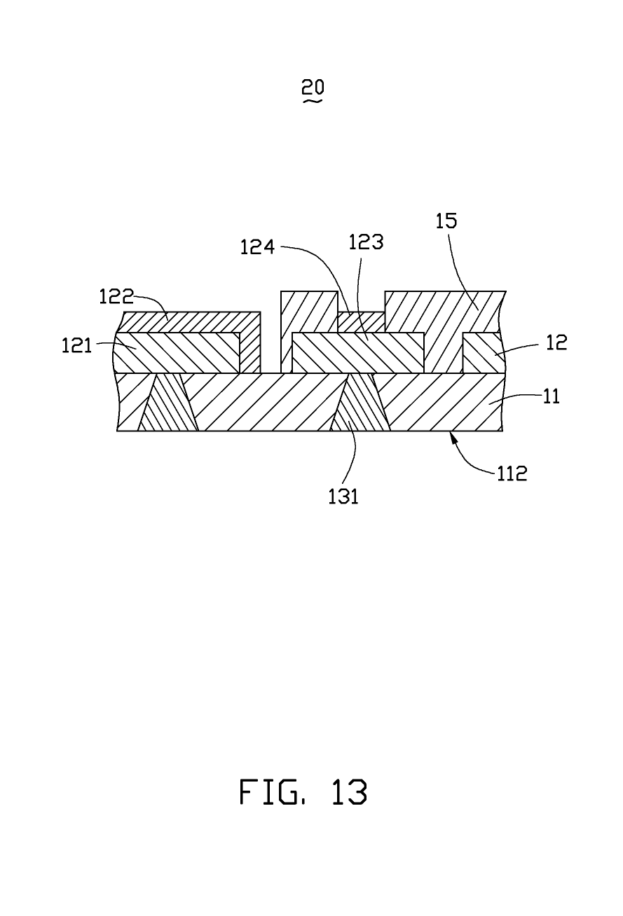

FIG. 13 shows steps 8, in which each via hole 13 in the circuit board unit 10g is filled with an electrically conductive material 131, thereby obtaining a packaging substrate 20. The electrically conductive material 131 may be made of copper, silver, for example, and may be formed by sputtering or printing. The electrically conductive material 131 in the via hole 13, which exposes the finger area 121, is securely connected to the finger area 121, and the electrically conductive material 131 in the via hole 13, which exposes the pad area 123, is securely connected to the pad area 123. In the present embodiment, each via hole 13 is fully filled with the electrically conductive material 131, and the surface of the electrically conductive material 131, which is adjacent to the second surface 112, is coplanar with the second surface 112. In alternative embodiments, the via hole 13 exposing the finger area 121 may be not filled with an electrically conductive material 131. In further alternative embodiments, the via hole 13 exposing the pad area 123 may be not filled with an electrically conductive material 131. In still further alternative embodiments, all of the via holes 13 may not be filled with the electrically conductive material 131. In such case, each circuit board units 10e can be a packaging substrate. In also still further alternative embodiments, each circuit board units 10e may includes a plurality of packaging substrates. In such case, the circuit board unit 10e should be cut to obtain separate packaging substrates.

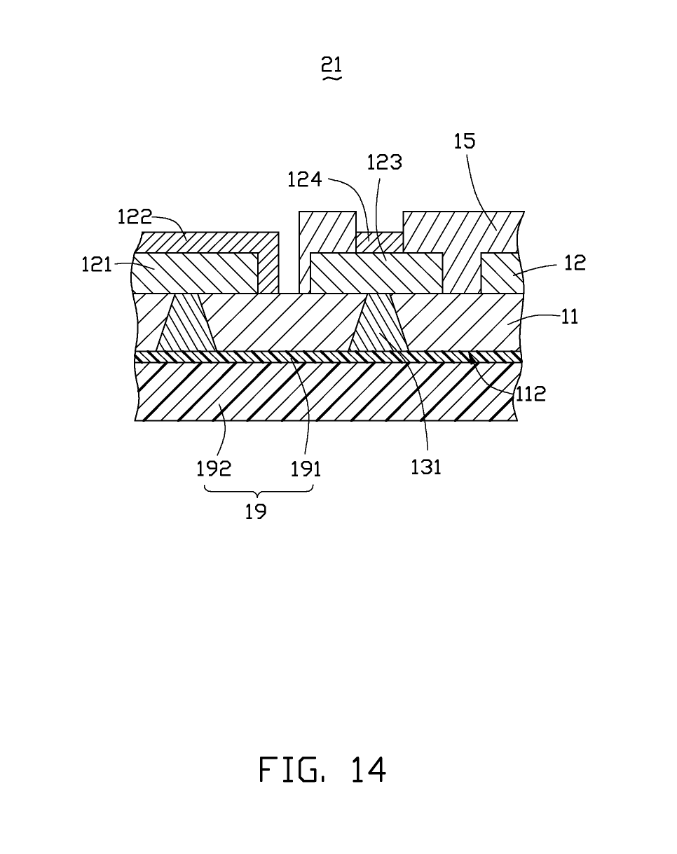

FIG. 14 shows step 9, in which a supporting substrate 19 is formed on the second surface 112 of the insulating layer 11, thereby obtaining a packaging substrate 21 with a backing. The supporting substrate 19 is configured for supporting the packaging substrate 20.

The supporting substrate 19 includes a supporting base 191 and an adhesive layer 192 on the supporting base 191. The supporting base 191 is adhered to the second surface 112 by the adhesive layer 192. The supporting base 191 may be made of epoxy, phenolic resin, or metal.

In the present embodiment, the flexible copper clad laminate 10a is processed in a roll-to-roll manner to manufacture the patterned flexible copper clad laminate 10a, and the patterned flexible copper clad laminate 10a is separated into a plurality of sheets 10c. Then, each sheets 10c is covered with a solder mask 15, and the plating layer 122 and the plating layer 124 are formed on each sheet 10c, thereby obtaining the sheet 10c with the plating layer 122 and the plating layer 124. The sheet 10c is stripped into a plurality of substrate strips 10d with circuit board units 10e. Each substrate strip 10d is cut into to obtain separate circuit board units 10e. Each circuit board unit 10e can be a packaging substrate. The efficiency of manufacturing the packaging substrate is thus improved.

The packaging substrate 20 includes the insulating layer 11, the wiring layer 12, and the solder mask 15. The wiring layer 12 includes a finger area 121 and a pad area 123.

The insulating layer 11 includes the first surface 111 and the second surface 112. Two via holes 13 are defined in the insulating layer 11, and passes through the first surface 111 and the second surface 112. One via hole 13 exposes the finger area 121 at the side of the second surface 112, and the other via hole 13 exposes the pad area 123 at the side of the second surface 112. Each via hole 13 is filled with the electrically conductive material 131. The electrically conductive material 131 in the via hole 13 exposing the finger area 121 is securely connected to the finger area 121, and the electrically conductive material 131 in the via hole 13 exposing the pad area 123 is securely connected to the pad area 123. In the present embodiment, the via hole 13 is fully filled with the electrically conductive material 131, and the surface of the electrically conductive material 131, which is adjacent to the second surface 112, is coplanar with the second surface 112.

The solder mask 15 covers the entire surface of the wiring layer 12 except pad area 123 or finger area 121 defined at predetermined positions on the wiring layer 12. The finger area 121 is located at the edge of the wiring layer 12, and the plating layer 122 is formed on the finger area 121. The plating layer 122 is electrically connected to the finger 121. The pad area 123 is located at the central area of the wiring layer 12, and the plating layer 124 is formed on the pad area 123. The plating layer 124 is electrically connected to the pad area 123.

In other embodiments, there may be two, three or more via holes 13; there may be two, three, or more fingers 121; and there may be two, three, or more pads 123. The number of the finger area 121 and the pad area 123 is equal to the number of the via holes 13; as such each of the finger area 121 and the pad area 123 spatially correspond to an via hole 13, respectively.

In other embodiments, the supporting substrate 19 may be formed on the second surface 112 to obtaining the packaging substrate 21 with a backing.

The insulation material of the packaging substrate 20 and the packaging substrate 21 with a backing is a flexible material. In addition, the wiring layer 12 is a single layer structure, and the packaging substrate 20 can thus be thinner.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a packaging substrate, comprising:
providing a roll of flexible copper clad laminate, the flexible copper clad laminate comprising a copper layer and an insulating layer;
forming a plurality of via holes to penetrate the insulating layer;
patterning the copper layer to form a wiring layer;
cutting the flexible copper clad laminated from roll type into a plurality of sheets, wherein each sheet has a plurality of substrate strips;
forming a solder mask on the sheet to cover the entire surface of the wiring layer except pad areas or finger areas defined at predetermined positions on the wiring layer;
forming a plating layer on each pad area or each finger area; and
stripping the plated sheet into a plurality of substrate strips with the solder mask, each substrate strip comprising a plurality of circuit board units, wherein before the step of cutting the patterned flexible copper clad laminate, the flexible copper clad laminate is transferred to each adjoined process in a roll-to-roll manner.

2. The method of claim 1, wherein a method of forming a plating layer on each pad area comprises:
forming a thin copper layer on a surface of the insulating layer furthest from the wiring layer, the inner surfaces of the via holes, and the surfaces of the pad areas exposed in the corresponding via holes by sputtering;
laminating a first dry film photoresist layer onto the thin copper layer, and entirely exposing the first dry film photoresist layer;
forming a plating layer on each pad area by electroplating; and
removing the exposed first dry film photoresist layer and the thin copper layer from the insulating layer to obtain the plated sheet.

3. The method of claim 1, wherein a method of patterning the copper layer to form a wiring layer comprises:
laminating a second dry film photoresist layer onto the copper layer, and laminating a third dry film photoresist layer onto the second surface;
selectively exposing the second dry film photoresist layer, entirely exposing the third dry film photoresist layer, and etching the copper layer into the wiring layer after developing;
stripping the second dry film photoresist layer and the third dry film photoresist from the insulating layer, thereby making the wiring and the insulating layer exposed outside.

4. The method of claim 1, wherein after stripping the plated sheet into a plurality of substrate strips with circuit board units, the method further comprises a step of cutting each substrate strip with circuit board units into separate circuit board units.

5. The method of claim 4, wherein after cutting each substrate strip with circuit board units into separate circuit board units, the method further comprises a step of filling the via hole using an electrically conductive material, the electrically conductive material being securely connected to the pad area.

6. The method of claim 5, wherein after filling the via hole using an electrically conductive material, the method further comprises a step of forming a supporting substrate on the surface of the insulating layer furthest from the wiring layer, the supporting substrate comprising a supporting base and an adhesive layer on the supporting base, the supporting base being adhered to the surface of the insulating layer furthest from the wiring layer by the adhesive layer.

7. The method of claim 5, wherein a surface of the electrically conductive material, which is furthest from the wiring layer, is coplanar with a surface of the insulating layer furthest from the wiring layer.

8. The method of claim 4, wherein after cutting each substrate strip with circuit board units into separate circuit board units, the method further comprises a step of forming a supporting substrate on the surface of the insulating layer furthest from the wiring layer, the supporting substrate comprising a supporting base and an adhesive layer on the supporting base, the supporting base being adhered to the surface of the insulating layer furthest from the wiring layer by the adhesive layer.

9. A packaging substrate, comprising a flexible insulating layer, an wiring layer and a solder mask, the flexible insulating layer and the solder mask being arranged on two opposite sides of the wiring layer, the flexible insulating layer defining an via hole, the wiring layer covering the via hole, the wiring layer comprising a pad area, two sides of the pad area respectively exposed outside from the solder mask and in the via hole.

10. The packaging substrate of claim 9, wherein the via hole is filled with an electrically conductive material, the electrically conductive material in the via hole is securely connected to the pad area.

11. The packaging substrate of claim 10, wherein a surface of the electrically conductive material, which is furthest from the wiring layer, is coplanar with a surface of the insulating layer furthest from the wiring layer.

12. The packaging substrate of claim 10, further comprising a supporting substrate, the supporting substrate arranged on the surface of the insulating layer furthest from the wiring layer, the supporting substrate comprising a supporting base and an adhesive layer on the supporting base, the supporting base being adhered to the surface of the insulating layer furthest from the wiring layer by the adhesive layer.

13. The packaging substrate of claim 9, further comprising a supporting substrate arranged on the surface of the insulating layer furthest from the wiring layer, the supporting substrate comprising a supporting base and an adhesive layer, the adhesive layer being sandwiched between the supporting base and the second surface.

14. The packaging substrate of claim 9, further comprising a plating layer on the pad area.

15. A packaging substrate, comprising a insulating layer, an wiring layer and a solder mask, the insulating layer and the solder mask being arranged on two opposite sides of the wiring layer, the insulating layer defining an via hole, the wiring layer covering the via hole, the wiring layer comprising a finger area, and two opposite sides of the finger area respectively exposed outside from the solder mask and in the via hole.

16. The packaging substrate of claim 15, wherein the via hole is filled with an electrically conductive material, the electrically conductive material in the via hole is securely connected to the finger area.

17. The packaging substrate of claim 16, wherein a surface of the electrically conductive material, which is furthest from the wiring layer, is coplanar with a surface of the insulating layer furthest from the wiring layer.

18. The packaging substrate of claim 16, further comprising a supporting substrate, the supporting substrate arranged on the surface of the insulating layer furthest from the wiring layer, the supporting substrate comprising a supporting base and an adhesive layer on the supporting base, the supporting base being adhered to the surface of the insulating layer furthest from the wiring layer by the adhesive layer.

19. The packaging substrate of claim 15, further comprising a supporting substrate arranged on the surface of the insulating layer furthest from the wiring layer, the supporting substrate comprising a supporting base and an adhesive layer, the adhesive layer being sandwiched between the supporting base and the second surface.

20. The packaging substrate of claim 9, further comprising a plating layer on the finger area.
